(19) United States
(12) Patent Application Publication
(10) Pub. No.: US 2023/0197799 A1
(43) Pub. Date: Jun. 22, 2023

(54) SEMICONDUCTOR DEVICE

(71) Applicant: ROHM CO., LTD., Kyoto-shi, Kyoto (JP)

(72) Inventor: Kohei MURASAKI, Kyoto-shi, Kyoto (JP)

(73) Assignee: ROHM CO., LTD., Kyoto-shi, Kyoto (JP)

(21) Appl. No.: 17/927,011

(22) PCT Filed: Aug. 2, 2021
(86) PCT No.: PCT/JP2021/028665

§ 371 Date: Nov. 22, 2022

(30) Foreign Application Priority Data
Aug. 11, 2020 (JP) 2020-135971

(51) Int. Cl. H01L 29/40; H01L 29/06; H01L 29/10; H01L 29/739

(52) U.S. Cl. CPC H01L 29/404; H01L 29/0696; H01L 29/1095; H01L 29/407; H01L 29/7397

(57) ABSTRACT

A semiconductor device includes a semiconductor layer which has a first principal surface and a second principal surface, a first conductive type drift region which is formed inside the semiconductor layer, a second conductive type base region which is formed on a surface layer portion of the drift region, a plurality of trench structures which include a first trench structure, a second trench structure and a third trench structure that are formed at intervals on the first principal surface so as to penetrate through the base region, a first region which is partitioned between the first trench structure and the second trench structure in the semiconductor layer, a second region which is partitioned between the second trench structure and the third trench structure in the semiconductor layer, a channel region which is controlled by the first trench structure, and a first conductive type high concentration region.

### TECHNICAL FIELD

This application corresponds to Japanese Patent Application No. 2020-135971 filed with the Japan Patent Office on Aug. 11, 2020, the entire disclosure of which is incorporated herein by reference. The present invention relates to a semiconductor device which has an IGBT (Insulated Gate Bipolar Transistor).

### BACKGROUND ART

Patent Literature 1 has disclosed a semiconductor device which has a trench-type IGBT. The semiconductor device includes a semiconductor layer which has one surface and another surface, a p type semiconductor region which is formed on a surface layer portion of one principal surface of the semiconductor layer, an n type semiconductor region which is formed on a surface layer portion of the other principal surface of the semiconductor layer, and a high concentration region which is formed between the p type semiconductor region and the n type semiconductor region and has an n type impurity concentration higher than the n type semiconductor region.

### CITATION LIST

### Patent Literature

Patent Literature 1: United States Patent Application Publication No.2018/083131

### SUMMARY OF INVENTION

### Technical Problem

One embodiment of the present invention provides a semiconductor device which has a novel structure.

### Solution to Problem

One embodiment of the present invention provides a semiconductor device including a semiconductor layer which has a first principal surface on one side and a second principal surface on the other side, a first conductive type drift region which is formed inside the semiconductor layer, a second conductive type base region which is formed on a surface layer portion of the drift region, a plurality of trench structures which include a first trench structure, a second trench structure and a third trench structure that are formed at intervals on the first principal surface so as to penetrate through the base region, a first region which is partitioned between the first trench structure and the second trench structure on the semiconductor layer, a second region which is partitioned between the second trench structure and the third trench structure on the semiconductor layer, a channel region which is controlled by the first trench structure, and a first conductive type high concentration region which has a first conductive type impurity concentration higher than the drift region and is formed in a region on the second principal surface side with respect to the base region on one side of one of the first region and the second region and is not formed on the other side of the first region or the second region.

Another embodiment provides a semiconductor device including a semiconductor layer which has a first principal surface on one side and a second principal surface on the other side, a first conductive type drift region which is formed inside the semiconductor layer, a second conductive type base region which is formed in a surface layer portion of the drift region, a plurality of trench structures which include a first trench structure, a second trench structure and a third trench structure which are formed at intervals on the first principal surface so as to penetrate through the base region, a first region which is partitioned between the first trench structure and the second trench structure in the semiconductor layer, a second region which is partitioned between the second trench structure and the third trench structure in the semiconductor layer, a channel region which is controlled by the first trench structure, and a first conductive type high concentration region which has a first conductive type impurity concentration higher than the drift region and is formed in a surface layer portion of the drift region so as to be connected to the base region from one direction along the first principal surface at least on one side of the first region and the second region.

The aforementioned or still other objects, features and effects of the present invention will be clarified by the following description of embodiments given below with reference to the accompanying drawings.

### BRIEF DESCRIPTION OF DRAWINGS

FIG. 1 is a plan view showing a semiconductor device according to a first embodiment of the present invention.

FIG. 2 is a plan view showing a structure of a first principal surface of a semiconductor layer.

FIG. 3 is an enlarged view of a region III shown in FIG. 1.

FIG. 4 is an enlarged view of a region IV shown in FIG. 3.

FIG. 5 is a cross-sectional view along line V-V shown in FIG. 4 and a cross-sectional view showing a first configuration example of the semiconductor device according to the first embodiment of the present invention.

FIG. 6 is a cross-sectional view showing a second configuration example of the semiconductor device shown in FIG. 1.

FIG. 7 is a cross-sectional view showing a third configuration example of the semiconductor device shown in FIG. 1.

FIG. 8 is a cross-sectional view showing a fourth configuration example of the semiconductor device shown in FIG. 1.

FIG. 9 is a cross-sectional view showing a semiconductor device of a second embodiment of the present invention, together with a structure according to the first configuration example.

FIG. 10 is a cross-sectional view showing a second configuration example of the semiconductor device shown in FIG. 9.

FIG. 11 is a cross-sectional view showing a third configuration example of the semiconductor device shown in FIG. 9.

FIG. 12 is a cross-sectional view showing a fourth configuration example of the semiconductor device shown in FIG. 9.

FIG. 13 is a plan view showing an internal structure of a semiconductor device according to a third embodiment of the present invention.

FIG. 14 is a cross-sectional view along line XIV-XIV shown in FIG. 13.

FIG. 15 is a cross-sectional view along line XV-XV shown in FIG. 13.

FIG. 16 is a cross-sectional view along line XVI-XVI shown in FIG. 13.

FIG. 17 is a plan view showing an internal structure of a semiconductor device according to a fourth embodiment of the present invention.

FIG. 18 is a cross-sectional view along line XVIII-XVIII shown in FIG. 17.

FIG. 19 is a cross-sectional view along line XIX-XIX shown in FIG. 17.

FIG. 20 is a cross-sectional view along line XX-XX shown in FIG. 17.

FIG. 21 is a plan view showing an internal structure of a semiconductor device according to a fifth embodiment of the present invention.

### DESCRIPTION OF EMBODIMENTS

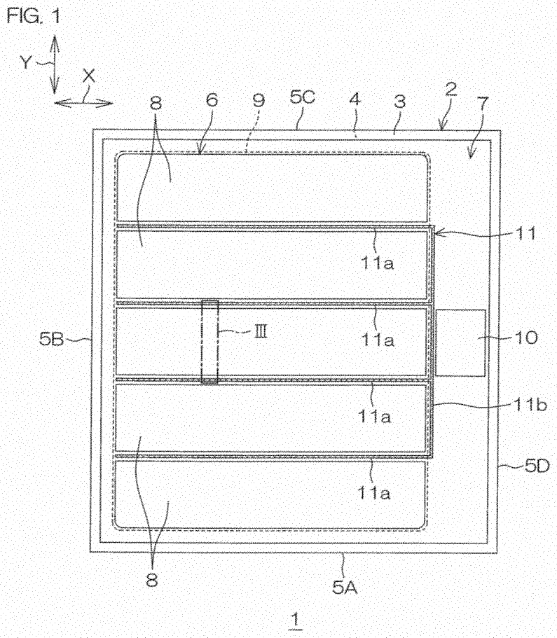

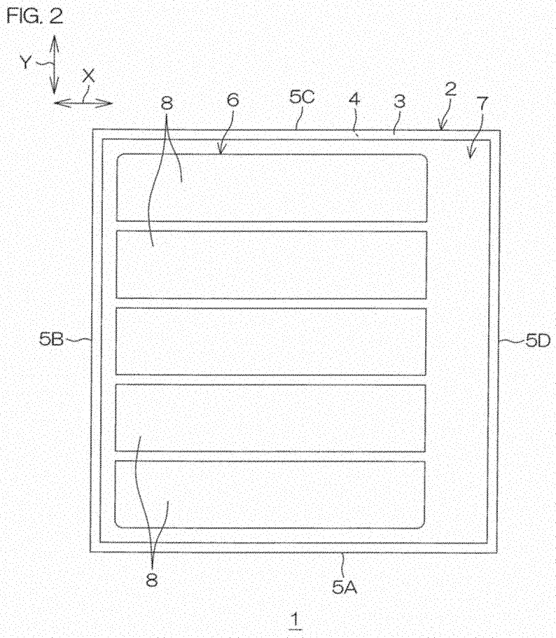

FIG. 1 is a plan view showing a semiconductor device 1 according to the first embodiment of the present invention. FIG. 2 is a plan view showing a structure of a first principal surface 3 of a semiconductor layer 2. The semiconductor device 1 is a semiconductor switching device (electronic component) which is equipped with an IGBT (Insulated Gate Bipolar Transistor). With reference to FIG. 1 and FIG. 2, the semiconductor device 1 includes a rectangular parallelepiped semiconductor layer 2. In this mode (this embodiment), the semiconductor layer 2 is constituted of an Si monocrystal. The semiconductor layer 2 has the first principal surface 3 on one side, a second principal surface 4 on the other side and side surfaces 5A, 5B, 5C, 5D which connect the first principal surface 3 and the second principal surface 4 together.

With reference to FIG. 1 and FIG. 2, the semiconductor device 1 includes the rectangular parallelepiped semiconductor layer 2. The semiconductor layer 2 has the first principal surface 3 on one side, the second principal surface 4 on the other side and the side surfaces 5A, 5B, 5C, 5D which connect the first principal surface 3 and the second principal surface 4 together. The first principal surface 3 and the second principal surface 4 are each formed in a quadrangular shape in a plan view seen from their normal directions Z (hereinafter, simply referred to as “in a plan view”). The side surfaces 5B and the side surface 5D extend along a first direction Y and face each other in a second direction X that intersects the first direction Y (specifically, orthogonal thereto). The side surface 5A and the side surface 5C extend along the second direction X and face each other in the first direction Y. A thickness of the semiconductor layer 2 may be not less than 50 μm and not more than 200 μm.

The semiconductor layer 2 includes an active region 6 and an external region 7. The active region 6 is a region in which an IGBT is formed. The active region 6 is set at a central portion of the semiconductor layer 2 at intervals in an inner region from the side surfaces 5A to 5D of the semiconductor layer 2 in a plan view. The active region 6 may be set in a rectangular shape having four sides parallel to the side surfaces 5A to 5D of the semiconductor layer 2 in a plan view.

The external region 7 is a region outside the active region 6. The external region 7 may extend in a band shape along a peripheral edge of the active region 6 in a plan view. The external region 7 may extend in an annular shape (in an endless shape) which surrounds the active region 6 in a plan view. The active region 6 includes at least one IGBT region 8 which is formed at intervals in the first direction Y. In this mode, the active region 6 includes plural rows of the IGBT regions 8. The plurality of IGBT regions 8 face each other in the first direction Y. The IGBT region 8 is a region in which the IGBT is formed. As shown in FIG. 1 and FIG. 2, the plurality of IGBT regions 8 may be formed in a quadrangular shape in a plan view. Specifically, the plurality of IGBT regions 8 may be formed in a rectangular shape longer in the first direction Y.

In the active region 6, an emitter terminal electrode 9 (refer to the broken line-given portion of FIG. 1) is formed above the first principal surface 3. The emitter terminal electrode 9 may contain at least one of aluminum, copper, an aluminum-silicon-copper alloy, an aluminum-silicon alloy and an aluminum-copper alloy. The emitter terminal electrode 9 may have a single layer structure which contains at least any one of them among these conductive materials. The emitter terminal electrode 9 may have a laminated structure in which at least two types of the conductive materials are laminated in a given order. In this mode, the emitter terminal electrode 9 is constituted of an aluminum-silicon-copper alloy.

The emitter terminal electrode 9 transmits an emitter signal to the active region 6 (IGBT region 8). An emitter potential may be a circuit reference potential which acts as a reference for circuit operation. The circuit reference potential may be a ground potential or may be a potential exceeding the ground potential. In the external region 7, a gate terminal electrode 10 is formed above the first principal surface 3. The gate terminal electrode 10 is formed in a quadrangular shape in a plan view. The gate terminal electrode 10 transmits a gate potential (gate signal) to the active region 6 (IGBT region 8). The gate terminal electrode 10 may be arranged in any position.

A gate wiring 11 is electrically connected to the gate terminal electrode 10. The gate terminal electrode 10 may contain at least one of aluminum, copper, an aluminum-silicon-copper alloy, an aluminum-silicon alloy and an aluminum-copper alloy. The gate terminal electrode 10 may have a single layer structure which contains any one of the conductive materials. The gate terminal electrode 10 may have a laminated structure in which at least two types of the conductive materials are laminated in any given order. In this mode, the gate terminal electrode 10 contains the same conductive material as the emitter terminal electrode 9.

The gate wiring 11 extends from the external region 7 toward the active region 6. The gate wiring 11 transmits a gate signal applied to the gate terminal electrode 10 to the active region 6 (IGBT region 8). Specifically, the gate wiring 11 includes an external region 11a which is positioned in the external region 7 and an internal region 11b which is positioned in the active region 6 and continues to the external region 11a. The external region 11a is electrically connected to the gate terminal electrode 10. In this mode, the external region 11a is selectively led around in a region on the side surface 5D side in the external region 7.

The plurality of internal regions 11b (four in the examples shown in FIG. 1 and FIG. 2) are formed in the active region 6. The plurality of internal regions 11b are formed at intervals in the first direction Y. The plurality of internal regions 11b extend in a band shape in the second direction X. The plurality of internal regions 11b each extend from a region on the side surface 5D side to a region on the side surface 5B side in the external region 7. The plurality of internal regions 11b may cross the active region 6.

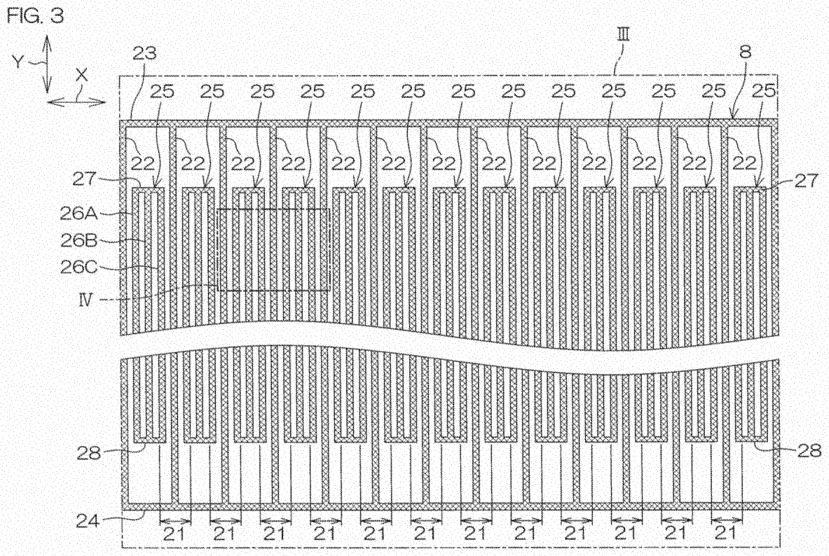

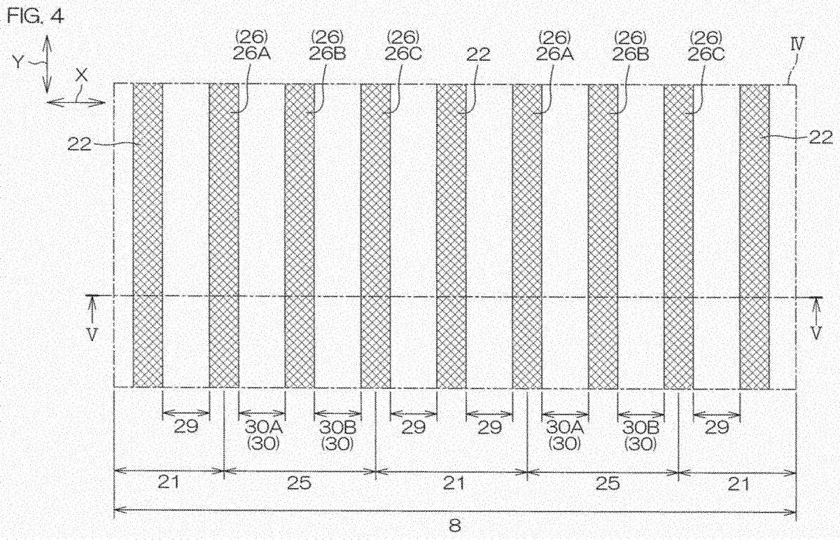

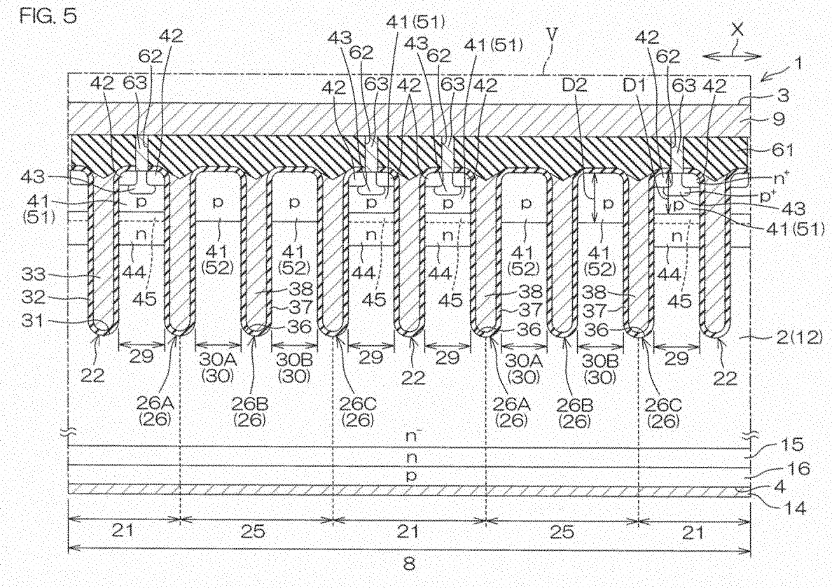

A gate signal applied to the gate terminal electrode 10 is transmitted to the internal region 11b via the external region 11a. Thereby, the gate signal is transmitted to the active region 6 (IGBT region 8) via the internal region 11b. FIG. 3 is an enlarged view of a region III shown in FIG. 1. FIG. 4 is an enlarged view of a region IV shown in FIG. 3. FIG. 5 is a cross-sectional view along line V-V shown in FIG. 4.

With reference to FIG. 3 to FIG. 5, an n− type drift region 12 is formed inside the semiconductor layer 2. Specifically, the drift region 12 is formed over an entire region of the semiconductor layer 2. An n type impurity concentration of the drift region 12 may be not less than 1.0×10¹³ cm⁻³ and not more than 1.0×10¹⁵ cm⁻³. In this mode, the semiconductor layer 2 has a single layer structure which includes an n− type semiconductor substrate 13. The semiconductor substrate 13 may be a silicon-made FZ substrate formed by an FZ (Floating Zone) method or a silicon-made MCZ substrate formed by an MCZ (Magnetic Field applied Czochralski) method. The drift region 12 is formed with the semiconductor substrate 13.

A collector terminal electrode 14 is formed on the second principal surface 4 of the semiconductor layer 2. The collector terminal electrode 14 is electrically connected to the second principal surface 4. Specifically, the collector terminal electrode 14 is electrically connected to the IGBT region 8 (collector region 16 to be described later). The collector terminal electrode 14 forms an ohmic contact with the second principal surface 4. The collector terminal electrode 14 transmits a collector signal to the IGBT region 8.

The collector terminal electrode 14 may contain at least one of a Ti layer, an Ni layer, an Au layer, an Ag layer and an Al layer. The collector terminal electrode 14 may have a laminated structure in which at least any two of the Ti layer, the Ni layer, the Au layer, the Ag layer and the Al layer are laminated in any given mode. An n type buffer layer 15 is formed on a surface layer portion of the second principal surface 4 of the semiconductor layer 2. The buffer layer 15 may be formed over an entire region of the surface layer portion of the second principal surface 4. An n type impurity concentration of the buffer layer 15 is larger than an n type impurity concentration of the drift region 12. The n type impurity concentration of the buffer layer 15 may be not less than 1.0×10¹⁴ cm⁻³ and not more than 1.0×10¹⁷ cm⁻³.

As shown in FIG. 5, each of the IGBT regions 8 includes a p type collector region 16 which is formed on the surface layer portion of the second principal surface 4 of the semiconductor layer 2. The collector region 16 is exposed from the second principal surface 4. The collector region 16 may be formed over an entire region of the surface layer portion of the second principal surface 4. A p type impurity concentration of the collector region 16 may be not less than 1.0×10¹⁵ cm⁻³ and not more than 1.0×10¹⁸ cm⁻³. The collector region 16 forms an ohmic contact with the collector terminal electrode 14.

In each of the IGBT regions 8, a p type base region 41 is formed on the surface layer portion of the first principal surface 3. A p type impurity concentration of the base region 41 may be not less than 1.0×10¹⁷ cm⁻³ and not more than 1.0×10¹⁸ cm⁻³. Each of the IGBT regions 8 includes an FET structure 21 which is formed on the first principal surface 3 of the semiconductor layer 2. In this mode, each of the IGBT regions 8 includes the FET structure 21 which is a trench gate type. Specifically, the FET structure 21 includes a trench gate structure (first trench structure) 22 which is formed on the first principal surface 3. A gate signal (gate potential) is applied to the trench gate structure 22. In FIG. 3 and FIG. 4, the trench gate structure 22 is shown by hatching.

The plurality of trench gate structures 22 are formed at intervals in the IGBT region 8 in the second direction X. A distance between the two trench gate structures 22 adjacent to each other in the second direction X may be not less than 1 μm and not more than 20 μm. Each of the trench gate structures 22 is formed in a band shape extending in the first direction Y in a plan view. The plurality of trench gate structures 22 are formed in a stripe shape as a whole in a plan view. The plurality of trench gate structures 22 have one end portion in the first direction Y and the other end portion in the first direction Y.

The FET structure 21 further includes a first external trench gate structure 23 and a second external trench gate structure 24. In FIG. 3, the first external trench gate structure 23 and the second external trench gate structure 24 are shown by hatching. The first external trench gate structure 23 extends in the second direction X and is connected to one end portion of the plurality of trench gate structures 22. The second external trench gate structure 24 extends in the second direction X and is connected to the other end portion of the plurality of trench gate structures 22.

The first external trench gate structure 23 and the second external trench gate structure 24 have the same structure as the trench gate structure 22 except that they extend in a different direction. Hereinafter, a description will be mainly given of a structure of the trench gate structure 22. Each of the trench gate structures 22 includes a gate trench 31 (first trench), a gate insulating film (first insulating film) 32 and a gate electrode (first electrode) 33.

The gate trench 31 is formed on the first principal surface 3 of the semiconductor layer 2. The gate trench 31 includes side walls and a bottom wall. The side walls of the gate trench 31 may be formed so as to be perpendicular to the first principal surface 3. The side walls of the gate trench 31 may be inclined downward from the first principal surface 3 toward the bottom wall. The gate trench 31 may be formed in a tapered shape in which an opening area on an opening side is larger than a bottom area. The bottom wall of the gate trench 31 may be formed so as to be parallel to the first principal surface 3. The bottom wall of the gate trench 31 may be formed in a convex curved shape toward the second principal surface 4.

The gate trench 31 penetrates through the base region 41. The bottom wall of the gate trench 31 is positioned further below than the bottom portion of the base region 41 with respect to the normal direction Z. A depth of the gate trench 31 may be not less than 2 μm and not more than 8 μm. A width of the gate trench 31 may be not less than 0.5 μm and not more than 3 μm. The gate insulating film 32 is formed in a film shape along an inner wall of the gate trench 31. The gate insulating film 32 partitions a recess space inside the gate trench 31. In this mode, the gate insulating film 32 includes a silicon oxide film. The gate insulating film 32 may include a silicon nitride film in place of or in addition to the silicon oxide film.

The gate electrode 33 is embedded in the gate trench 31, with the gate insulating film 32 held between the gate electrode 33 and the gate trench 31. The gate electrode 33 is controlled by a gate signal (gate potential). The gate electrode 33 may contain conductive polysilicon. The gate electrode 33 is formed in a wall shape extending along the normal direction Z in a cross-sectional view. The gate electrode 33 has an upper end portion which is positioned on the opening side of the gate trench 31. The upper end portion of the gate electrode 33 is positioned on the bottom wall side of the gate trench 31 with respect to the first principal surface 3. The gate electrode 33 is electrically connected to the gate wiring 11 in a region which is not shown. A gate signal applied to the gate terminal electrode 10 is transmitted to the gate electrode 33 via the gate wiring 11.

Each of the IGBT regions 8 includes a region separation structure 25 which partitions the FET structure 21 from other regions on the first principal surface 3 of the semiconductor layer 2. The region separation structure 25 is formed in a region adjacent to the FET structure 21 in the surface layer portion of the first principal surface 3. The region separation structure 25 is formed on both sides of the FET structure 21. The region separation structure 25 is formed in a region between two FET structures 21 which are adjacent to each other. Thereby, the plurality of FET structures 21 are separated by the region separation structure 25. The region separation structure 25 is formed in a closed region which is partitioned by the two adjacent trench gate structures 22, the first external trench gate structure 23 and the second external trench gate structure 24.

The region separation structure 25 includes a plurality of separation trench structures 26 (three in the example of FIG. 3) extending in the first direction Y. In FIG. 3 and FIG. 4, the plurality of separation trench structures 26 are shown by hatching. The plurality of separation trench structures 26 are formed at intervals in the second direction X in the IGBT region 8. In this mode, the plurality of separation trench structures 26 include a first separation trench structure 26A (second trench structure), a second separation trench structure 26B (third trench structure) and a third separation trench structure 26C (fourth trench structure).

The first separation trench structure 26A is formed at intervals from one trench gate structure 22 on one side in the second direction X (on the right side of the paper in FIG. 3 and FIG. 4). The second separation trench structure 26B is formed at intervals from the first separation trench structure 26A on one side in the second direction X. The third separation trench structure 26C is formed at intervals from the second separation trench structure 26B on one side in the second direction X. The second separation trench structure 26B is held between the first separation trench structure 26A and the third separation trench structure 26C in the second direction X.

Each of the separation trench structures 26 is formed in a band shape extending in the first direction Y in a plan view. The plurality of separation trench structures 26 are formed in a stripe shape as a whole. The plurality of separation trench structures 26 have one end portion in the first direction Y and the other end portion in the first direction Y. A distance between the trench gate structure 22 and the separation trench structure 26 (first separation trench structure 26A) in the second direction X may be not less than 0.5 μm and not more than 5 μm. A distance between two adjacent separation trench structures 26 in the second direction X may be not less than 0.5 μm and not more than 5 μm. It is preferable that the distance between the two adjacent separation trench structures 26 in the second direction X is substantially equal to the distance between the trench gate structure 22 and the separation trench structure 26 (first separation trench structure 26A) in the second direction X.

The region separation structure 25 further includes a first external separation trench structure 27 and a second external separation trench structure 28. In FIG. 3, the first external separation trench structure 27 and the second external separation trench structure 28 are shown by hatching. The first external separation trench structure 27 extends in the second direction X and is connected to one end portion of the plurality of separation trench structures 26. The second external separation trench structure 28 extends in the second direction X and is connected to the other end portion of the plurality of separation trench structures 26.

The first external separation trench structure 27 and the second external separation trench structure 28 have the same structure as the separation trench structure 26 except that they extend in a different direction. Hereinafter, a structure of the separation trench structure 26 will be mainly described. Each of the separation trench structures 26 includes a separation trench 36 (second trench, third trench), a separating/insulating film 37 (second insulating film, third insulating film) and a separation electrode 38 (second electrode, third electrode). The separation trench 36 is formed in the first principal surface 3 of the semiconductor layer 2. The separation trench 36 includes a side wall and a bottom wall. The side wall of the separation trench 36 may be formed so as to be perpendicular to the first principal surface 3.

The side wall of the separation trench 36 may be inclined downward from the first principal surface 3 toward the bottom wall. The separation trench 36 may be formed in a tapered shape in which an opening area on the opening side is larger than a bottom area. The bottom wall of the separation trench 36 may be formed so as to be parallel to the first principal surface 3. The bottom wall of the separation trench 36 may be formed in a convex curved shape toward the second principal surface 4. A depth of the separation trench 36 may be not less than 2 μm and not more than 8 μm. A width of the separation trench 36 may be not less than 0.5 μm and not more than 3 μm. The width of the separation trench 36 is a width of the separation trench 36 in the second direction X. The width of the separation trench 36 may be equal to a width of the gate trench 31.

The separating/insulating film 37 is formed in a film shape along an inner wall of the separation trench 36. The separating/insulating film 37 partitions a recess space inside the separation trench 36. In this mode, the separating/insulating film 37 includes a silicon oxide film. The separating/insulating film 37 may include a silicon nitride film in place of or in addition to the silicon oxide film. The separation electrode 38 is embedded in the separation trench 36, with the separating/insulating film 37 held between the separation electrode 38 and the separation trench 36. The separation electrode 38 is electrically connected to the emitter terminal electrode 9 in a region which is not shown. An emitter potential is applied to the separation electrode 38. The separation electrode 38 may contain conductive polysilicon.

The separation electrode 38 is formed in a wall shape extending along the normal direction Z in a cross-sectional view. The separation electrode 38 has an upper end portion which is positioned on the opening side of the separation trench 36. The upper end portion of the separation electrode 38 is positioned on the bottom wall side of the separation trench 36 with respect to the first principal surface 3. The plurality of separation trench structures 26 partition the first region 29 with the trench gate structure 22 in the semiconductor layer 2 of the FET structure 21 in a cross-sectional view along the second direction X. The first region 29 is formed on both sides of the trench gate structure 22. The first region 29 is also a region in which the FET structure 21 is formed. That is, in this mode, each of the FET structures 21 includes two first regions 29 which are adjacent to each other in the first direction Y.

One of the two first regions 29 is partitioned between the trench gate structure 22 and the first separation trench structure 26A. The other of the two first regions 29 is partitioned between the trench gate structure 22 and the third separation trench structure 26C. These two first regions 29 are each formed in a band shape extending along the trench gate structure 22 and the separation trench structure 26.

The plurality of separation trench structures 26 partition a second region 30 of the region separation structure 25 in the semiconductor layer 2 in a cross-sectional view along the second direction X. In this mode, the plurality of separation trench structures 26 partition the plurality of second regions 30 adjacent to each other in the first direction Y in the semiconductor layer 2. In this mode, each of the region separation structures 25 includes two second regions 30 adjacent to each other in the first direction Y.

Of two second regions 30, one side region 30A on one side (on the left side of the paper in FIG. 5) is partitioned between the first separation trench structure 26A and the second separation trench structure 26B. Of the two second regions 30, the other side region 30B on the other side (on the right side of the paper in FIG. 5) is partitioned between the second separation trench structure 26B and the third separation trench structure 26C. The two second regions 30 are each formed in a band shape extending along the plurality of separation trench structures 26.

In this mode, in a state that the plurality of second regions 30 (two in this mode) hold the plurality of first regions 29 (two in this mode) therebetween in the IGBT region 8, the plurality of second regions 30 are alternately arranged with the plurality of first regions 29 in the second direction X. The plurality of first regions 29 and the plurality of second regions 30 are formed in a stripe shape as a whole in a plan view. In the IGBT region 8, there is formed an IE (Injection Enhanced: carrier injection promotion) structure which includes the FET structure 21 and the region separation structure 25. In the IE structure, the plurality of FET structures 21 are kept separated in the second direction X by the region separation structure 25.

The region separation structure 25 limits migration of holes injected into the semiconductor layer 2. That is, the holes flow into the FET structure 21 all the way around the region separation structure 25. Thereby, the holes accumulate in a region immediately under the FET structure 21 in the semiconductor layer 2, resulting in an increase in density of the holes. As a result, an on-resistance is reduced and an on-voltage is reduced (IE effects). An n⁺ type emitter region 42 is formed on a surface layer portion of the base region 41 in the FET structure 21. An n type impurity concentration of the emitter region 42 is larger than an n type impurity concentration of the drift region 12. The n type impurity concentration of the emitter region 42 may be not less than 1.0×10¹⁹ cm⁻³ and not more than 1.0×10²¹ cm⁻³.

The emitter region 42 is formed on both sides of the trench gate structure 22. The emitter region 42 is formed in a band shape extending along the trench gate structure 22 in a plan view. The emitter region 42 is exposed from the first principal surface 3 and the side walls of the gate trench 31. A bottom portion of the emitter region 42 is formed in a region between an upper end portion of the gate electrode 33 and a bottom portion of the base region 41 with respect to the normal direction Z.

In each of the first regions 29, there is formed a p⁺ type contact region 43 on a surface layer portion of the base region 41. A p type impurity concentration of the contact region 43 is larger than a p type impurity concentration of the base region 41. The p type impurity concentration of the contact region 43 may be not less than 1.0×10¹⁹ cm⁻³ and not more than 1.0×10²⁰ cm⁻³. An n⁺ type high concentration region 44 is formed at a region on the second principal surface 4 side with respect to the base region 41 in the semiconductor layer 2. An n type impurity concentration of the high concentration region 44 is larger than an n type impurity concentration of the drift region 12. The n type impurity concentration of the high concentration region 44 may be not less than 1.0×10¹⁵ cm⁻³ and not more than 1.0×10¹⁷ cm⁻³.

The high concentration region 44 is formed in a region of the first region 29 on the second principal surface 4 side with respect to the base region 41 in the semiconductor layer 2 and is not formed in the second region 30. That is, in the IGBT region 8, the high concentration region 44 is formed in the first region 29 of the FET structure 21 and the high concentration region 44 is not formed in the one side region 30A or the other side region 30B of the region separation structure 25. The high concentration region 44 is formed in a region on the second principal surface 4 side with respect to the base region 41 so as to be connected to the base region 41 in the first region 29.

The high concentration region 44 is formed at a depth position between the base region 41 and a bottom wall of the gate trench 31. The high concentration region 44 is formed at intervals from the bottom wall of the gate trench 31 on the base region 41 side. The high concentration region 44 exposes a part of a side wall of the gate trench 31 and the bottom wall thereof. The high concentration region 44 faces the gate electrode 33 on the side wall of the gate trench 31, with the gate insulating film 32 held between the high concentration region 44 and the gate electrode 33.

The high concentration region 44 is formed at a depth position between the base region 41 and a bottom wall of the separation trench 36. The high concentration region 44 is formed at intervals from the bottom wall of the separation trench 36 on the base region 41 side. The high concentration region 44 exposes a part of a side wall of the separation trench 36 and the bottom wall thereof. The high concentration region 44 faces the separation electrode 38 in the side wall of the separation trench 36, with the separating/insulating film 37 held between the high concentration region 44 and the separation electrode 38.

The high concentration region 44 is formed in a band shape extending in the second direction X along the trench structures 22, 26 in a plan view. As shown in FIG. 5, an upper portion of the high concentration region 44 and a bottom portion of the high concentration region 44 are both positioned further above than a central position of the trench structures 22, 26 in a depth direction with respect to the normal direction Z. That is, the high concentration region 44 is formed so as to be shallower than the central position of the trench structures 22, 26 in the depth direction.

The high concentration region 44 may be formed so as to be deeper than the central position of the trench structures 22, 26 in the depth direction. It is preferable that the high concentration region 44 is formed so as to be shallower than the central position of the trench structures 22, 26 in the depth direction. The high concentration region 44 is formed at least in one of two first regions 29. In this mode, the high concentration region 44 is formed in both of the two first regions 29.

The high concentration region 44 has an n type compensation region 45 which contains a p type impurity and an n type impurity at a connection portion with the base region 41 in the first region 29. “Compensation” is also referred to as “offset,” “compensation,” “carrier offset” or “carrier compensation.” The compensation region 45 is a region in which a part of the n type impurity of the high concentration region 44 is compensated by a part of the p type impurity of the base region 41, thereby giving an n type semiconductor region as a whole. An n type impurity concentration of the compensation region 45 is lowered by such an extent that is compensated from the n type impurity concentration of the high concentration region 44 by the p type impurity of the base region 41.

In other words, the p type impurity concentration of the base region 41 on the bottom portion side is lowered by an extent that is compensated by the n type impurity concentration of the high concentration region 44. The base region 41 includes a first portion 51 which is formed at a relatively shallow region in the first region 29 and a second portion 52 which is formed so as to be deeper than the first portion 51 in the second region 30. The first portion 51 has a first depth D1. The first portion 51 is a region which is thinned (made shallow) by the high concentration region 44 (compensation region 45) in the first region 29. It is a region which is not thinned (made shallow) by the high concentration region 44 in the second region 30. The second portion 52 has a second depth D2 exceeding the first depth D1.

The high concentration region 44 functions as a carrier storage region which suppresses a carrier (holes) supplied to the semiconductor layer 2 from being led back (discharged) to the base region 41. Thereby, holes accumulate at a region immediately under the FET structure 21 in the semiconductor layer 2. As a result, an on-resistance is reduced and an on-voltage is reduced. As described so far, in the first region 29, the base region 41 and the emitter region 42 face the gate electrode 33, with the gate insulating film 32 held between the base region 41/the emitter region 42 and the gate electrode 33. In this mode, the high concentration region 44 also faces the gate electrode 33, with the gate insulating film 32 held between the high concentration region 44 and the gate electrode 33.

The FET structure 21 includes a channel region which is controlled by the trench gate structure 22 in the surface layer portion of the base region 41. The channel region is formed at a region between the emitter region 42 and the drift region 12 (high concentration region 44) in the base region 41. An interlayer insulating layer 61 is formed on the first principal surface 3 in the IGBT region 8. The interlayer insulating layer 61 is formed in a film shape along the first principal surface 3. The interlayer insulating layer 61 may have a laminated structure which includes a plurality of insulating layers. The interlayer insulating layer 61 may contain oxide silicon or nitride silicon. The interlayer insulating layer 61 may contain at least one of NGS (Non-doped Silicate Glass), PSG (Phosphor Silicate Glass) and BPSG (Boron Phosphor Silicate Glass). A thickness of the interlayer insulating layer 61 may be not less than 0.1 μm and not more than 2 μm.

As shown in FIG. 5, a plurality of first emitter openings 62 are each formed at a position corresponding to the contact region 43 in the interlayer insulating layer 61. The plurality of first emitter openings 62 vertically penetrate through the interlayer insulating layer 61 to expose each of the corresponding first regions 29. As shown in FIG. 5, a first contact electrode 63 is embedded in each of the plurality of first emitter openings 62. The plurality of first contact electrodes 63 are each electrically connected to the emitter region 42 and the contact region 43 inside the corresponding first emitter opening 62.

The plurality of first contact electrodes 63 are electrically connected to the first region 29 in the FET structure 21 and is not connected to the one side region 30A or the other side region 30B of the second region 30 in the region separation structure 25. Therefore, the base region 41 on the region separation structure 25 side (that is, the second portion 52) is formed in an electrically floating state. That is, the base region 41 on the region separation structure 25 side (that is, the second portion 52) functions as a p type floating region.

The first contact electrode 63 may have a laminated structure which includes a barrier electrode layer and a main electrode layer that are not shown. The barrier electrode layer is formed in a film shape along an inner wall of the first emitter opening 62. The barrier electrode layer may have a single layer structure which includes a titanium layer or a titanium nitride layer. The barrier electrode layer may have a laminated structure which includes a titanium layer and a titanium nitride layer. In this case, the titanium nitride layer may be laminated on the titanium layer. The main electrode layer is embedded in the first emitter opening 62, with the barrier electrode layer held between the main electrode layer and the first emitter opening 62. The main electrode layer may contain tungsten.

The aforementioned emitter terminal electrode 9 and the gate terminal electrode 10 are formed on the interlayer insulating layer 61. As shown in FIG. 5, the emitter terminal electrode 9 is electrically connected to the emitter region 42 and the contact region 43 via the first contact electrode 63 on the interlayer insulating layer 61. Further, although not shown in the drawing, a plurality of contact electrodes for separation electrodes which electrically connect the emitter terminal electrode 9 and the separation electrode 38 together are provided. Although not shown in the drawing, a plurality of emitter openings for separation electrodes are formed at a position corresponding to the separation electrode 38 in the interlayer insulating layer 61. The contact electrodes for the separation electrodes are each electrically connected to a corresponding separation electrode 38 via an emitter opening for the separation electrodes.

A pad electrode may be formed on the emitter terminal electrode 9. The pad electrode may include at least one of a nickel layer, a palladium layer and a gold layer. The pad electrode may have a laminated electrode which includes a nickel layer, a palladium layer and a gold layer laminated in this order from the emitter terminal electrode 9 side.

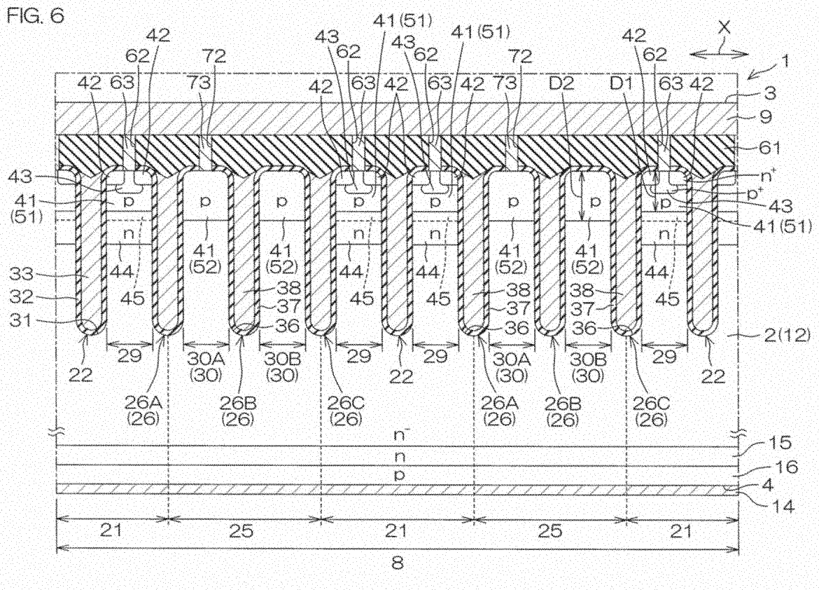

FIG. 6 is a cross-sectional view showing a second configuration example of the semiconductor device 1. FIG. 6 is a cross-sectional view corresponding to FIG. 5. In FIG. 6, the same reference signs as those of FIG. 1 to FIG. 5 are given to portions common to those of the first configuration example, and a specific description thereof is omitted.

The second configuration example is different from the first configuration example in that an emitter terminal electrode 9 is electrically connected to a base region 41 of the one side region 30A in addition to a base region 41 of a first region 29 and is not electrically connected to a base region 41 of the other side region 30B. The base region 41 of the other side region 30B is formed in an electrically floating state. Specifically, a second emitter opening 72 is formed at a position corresponding to the base region 41 of the one side region 30A in an interlayer insulating layer 61. The second emitter opening 72 vertically penetrates through the interlayer insulating layer 61 to expose the base region 41 of the one side region 30A.

A second contact electrode 73 is embedded in the second emitter opening 72 of the interlayer insulating layer 61. The second contact electrode 73 is electrically connected to the base region 41 of the one side region 30A via the second emitter opening 72. The emitter terminal electrode 9 is electrically connected to the second contact electrode 73 on the interlayer insulating layer 61. The second contact electrode 73 may have a laminated structure which includes a barrier electrode layer and a main electrode layer, as with a first contact electrode 63. Otherwise, specific description of the second contact electrode 73 is omitted here.

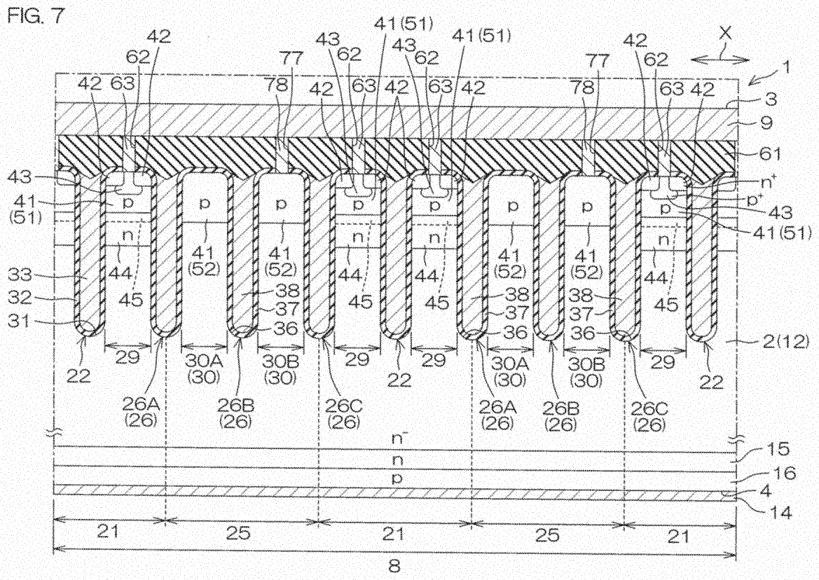

FIG. 7 is a cross-sectional view showing a third configuration example of the semiconductor device 1. FIG. 7 is a cross-sectional view corresponding to FIG. 5. In FIG. 7, the same reference signs as those of FIG. 1 to FIG. 5 are given to portions common to those of the first configuration example, and a specific description thereof is omitted. The third configuration example is different from the first configuration example in that an emitter terminal electrode 9 is electrically connected to a base region 41 of the other side region 30B in addition to a base region 41 of a first region 29 and is not electrically connected to a base region 41 of the one side region 30A. The base region 41 of the one side region 30A is formed in an electrically floating state.

Specifically, a third emitter opening 77 is formed at a position corresponding to the base region 41 of the other side region 30B in an interlayer insulating layer 61. The third emitter opening 77 vertically penetrates through the interlayer insulating layer 61 to expose the base region 41 of the other side region 30B. A third contact electrode 78 is embedded in the third emitter opening 77 of the interlayer insulating layer 61. The third contact electrode 78 is electrically connected to the base region 41 of the other side region 30B via the third emitter opening 77. The emitter terminal electrode 9 is electrically connected to the third contact electrode 78 on the interlayer insulating layer 61. The third contact electrode 78 may have a laminated structure which includes a barrier electrode layer and a main electrode layer, as with a first contact electrode 63. Otherwise, specific description of the third contact electrode 78 is omitted here.

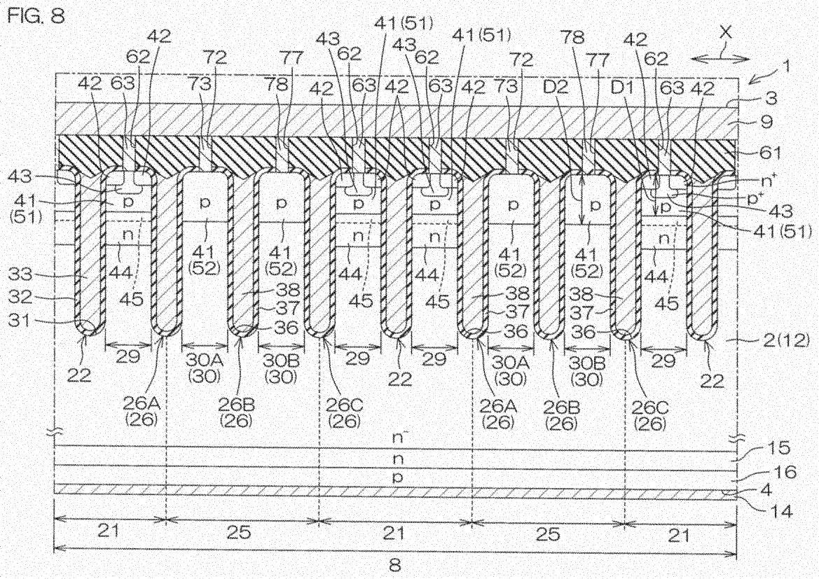

FIG. 8 is a cross-sectional view showing a fourth configuration example of the semiconductor device 1. FIG. 8 is a cross-sectional view corresponding to FIG. 5. In FIG. 8, the same reference signs as those of FIG. 1 to FIG. 7 are given to portions common to those of the first configuration example, and a specific description thereof is omitted. The fourth configuration example is different from the first configuration example in that an emitter terminal electrode 9 is electrically connected to both a base region 41 of the one side region 30A and a base region 41 of the other side region 30B in addition to a base region 41 of a first region 29. That is, the semiconductor device 1 according to the fourth configuration example includes a second emitter opening 72 and a second contact electrode 73 (refer to FIG. 6) as well as a third emitter opening 77 and a third contact electrode 78 (refer to FIG. 7).

The second contact electrode 73 is electrically connected to the base region 41 of the one side region 30A via the second emitter opening 72. The third contact electrode 78 is electrically connected to the base region 41 of the other side region 30B via the third emitter opening 77. The emitter terminal electrode 9 is electrically connected to the second contact electrode 73 and the third contact electrode 78 on an interlayer insulating layer 61.

Where a collector-emitter voltage VCE is increased, in an IGBT, a collector current is monotonically increased in association with an increase in collector-emitter voltage VCE. The collector-emitter voltage VCE is a voltage between a collector and an emitter of the IGBT. When the collector-emitter voltage VCE exceeds a predetermined value, the collector current is saturated. A region in which a rate of increase in collector current Ic is relatively small with respect to a rate of increase in collector-emitter voltage VCE is given as a saturation region. The voltage value between the collector and the emitter which is obtained when a designated voltage (for example, 15V) is applied between the gate and the emitter and a rated collector current is allowed to flow is given as a “saturation voltage VCE (sat).”

Values of the saturation voltage between the collector and the emitter VCE (sat) in the first to the fourth configuration example are respectively tabulated in Table 1 given below. In Table 1 below, values of saturation voltage VCE (sat) when a rated collector current is 30 A are shown. In Table 1, values of saturation voltage VCE (sat) in a first to a fourth reference example are shown. The first to the fourth reference example respectively correspond to the first to the fourth configuration example. Specifically, the first reference example has a structure in which the n⁺ type high concentration region 44 is removed from the first configuration example. Similarly, the second to the fourth reference example have the respective structures in which the n⁺ type high concentration region 44 is removed from the second to the fourth configuration example.

TABLE 1

| | Vce (sat) (V) |
|---|---|
| First example | 1.31 |
| Second example | 1.48 |
| Third example | 1.38 |
| Fourth example | 1.52 |
| First reference example | 1.38 |
| Second reference example | 1.45 |
| Third reference example | 1.41 |
| Fourth reference example | 1.48 |

Table 1 clearly shows that, in the semiconductor device 1 of the first embodiment, a minimum value (1.31V) of the saturation voltage VCE (sat) is smaller than those of the reference examples and a maximum value (1.52V) of the saturation voltage VCE (sat) is larger than those of the reference examples. Therefore, a voltage difference (0.21V) between the maximum value and the minimum value of the saturation voltage VCE (sat) in the examples is larger than that in the reference examples. As described so far, a mode of the semiconductor device 1 is changed from the first to the fourth reference example to the first to the fourth configuration example (that is, the high concentration region 44 is introduced), thus making it possible to adjust the values of the saturation voltage VCE (sat) without changing the basic layout. As described so far, according to this mode, it is possible to provide the semiconductor device 1 which has a structure in which the saturation voltage VCE (sat) is adjusted by a novel structure.

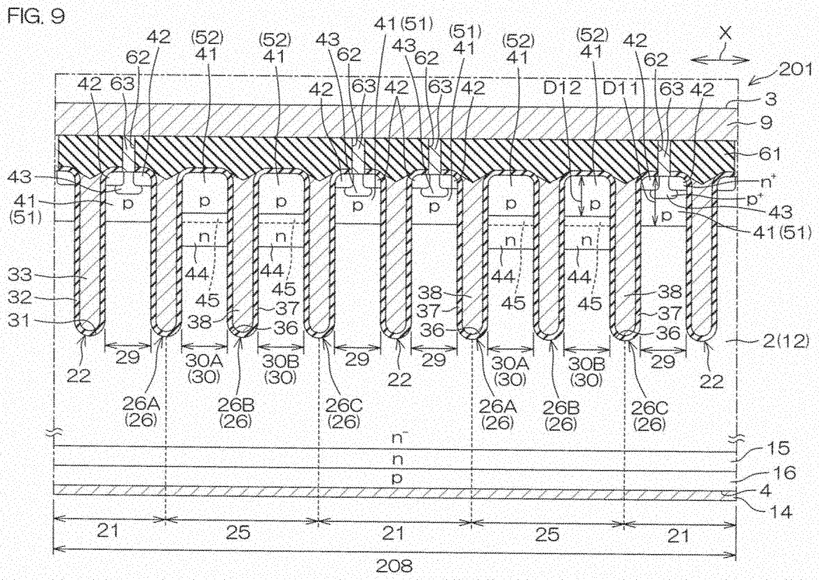

FIG. 9 is a cross-sectional view showing a semiconductor device 201 according to the second embodiment of the present invention, together with the structure of the first configuration example. FIG. 9 is a cross-sectional view corresponding to FIG. 5. In FIG. 9, the same reference signs as those of FIG. 1 to FIG. 5 are given to portions common to those of the first embodiment, and a specific description thereof is omitted. The semiconductor device 201 according to the second embodiment has an IGBT region 208 in place of the IGBT region 8.

The IGBT region 208 is different from the IGBT region 8 according to the first embodiment (the first configuration example thereof) in that a high concentration region 44 is formed in a second region 30 of a region separation structure 25 (at least one of the one side region 30A and the other side region 30B) in place of a first region 29. In this mode, the high concentration region 44 is formed in both of the one side region 30A and the other side region 30B. In the other respects, the IGBT region 208 is common to the IGBT region 8 according to the first embodiment (the first configuration example thereof).

The high concentration region 44 is formed in a region on a second principal surface 4 side with respect to a base region 41 in a semiconductor layer 2 of the second region 30 and is not formed in the first region 29. That is, in the IGBT region 208, the high concentration region 44 is formed in the one side region 30A and the other side region 30B of the region separation structure 25, and the high concentration region 44 is not formed in a first region 29 of an FET structure 21. The high concentration region 44 is formed in a region on the second principal surface 4 side with respect to the base region 41 so as to be connected to the base region 41 in the second region 30.

The high concentration region 44 is formed in a band shape extending in a second direction X along a separation trench structure 26 in a plan view. The high concentration region 44 is formed at a depth position between the base region 41 and a bottom wall of a separation trench 36 in the second region 30. The high concentration region 44 is formed at a depth position between the base region 41 and the bottom wall of the separation trench 36. The high concentration region 44 is formed at intervals from the bottom wall of the separation trench 36 on the base region 41 side. The high concentration region 44 exposes a part of a side wall of the separation trench 36 and the bottom wall thereof. The high concentration region 44 faces a separation electrode 38 in the side wall of the separation trench 36, with a separating/insulating film 37 held between the high concentration region 44 and the separation electrode 38.

The high concentration region 44 is formed so as to be shallower than a central position of the separation trench structure 26 in a depth direction. The high concentration region 44 may be formed so as to be deeper than the central position of the separation trench structure 26 in the depth direction. It is preferable that the high concentration region 44 is formed so as to be shallower than the central position of the separation trench structure 26 in the depth direction. The high concentration region 44 has an n type compensation region 45 which contains a p type impurity and an n type impurity at a connection portion with the base region 41 in the second region 30.

The base region 41 includes a first portion 51 which is formed at a relatively deep region in the first region 29 and a second portion 52 which is formed at a region shallower than the first portion 51 in the second region 30. The first portion 51 has a first depth D11. The first portion 51 is a region which is not thinned (made shallow) by the high concentration region 44 in the first region 29. The second portion 52 has a second depth D12 less than the first depth D11. The second portion 52 is a region which is thinned (made shallow) by the high concentration region 44 (compensation region 45) in the second region 30.

A plurality of first contact electrodes 63 are each electrically connected to the first region 29 via a plurality of first emitter openings 62 and is not electrically connected to the second region 30. An emitter terminal electrode 9 is electrically connected to the base region 41 of the first region 29 via the first contact electrode 63. Therefore, the base regions 41 on the second region 30 side are each formed in an electrically floating state. That is, in this mode, the high concentration region 44 is formed in a region immediately under the base region 41 as a floating region in the second region 30.

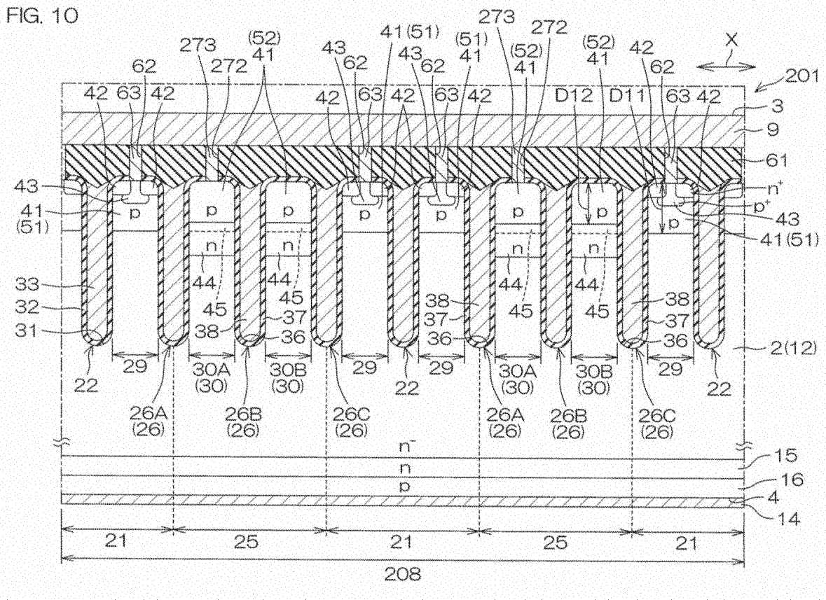

FIG. 10 is a cross-sectional view showing a second configuration example of the semiconductor device 201. FIG. 10 is a cross-sectional view corresponding to FIG. 5. In FIG. 10, the same reference signs as those of FIG. 9 are given to portions common to those of the first configuration example, and a specific description is omitted. The second configuration example is different from the first configuration example in that an emitter terminal electrode 9 is electrically connected to a base region 41 of the one side region 30A in addition to a base region 41 of a first region 29 and is not connected to a base region 41 of the other side region 30B. That is, while the base region 41 of the one side region 30A is emitter-grounded, the base region 41 of the other side region 30B is formed in an electrically floating state.

Specifically, a second emitter opening 272 is formed at a position corresponding to the base region 41 in an interlayer insulating layer 61. The second emitter opening 272 vertically penetrates through the interlayer insulating layer 61 to expose only the base region 41 of the one side region 30A. A second contact electrode 273 is embedded in the second emitter opening 272 of the interlayer insulating layer 61. The second contact electrode 273 is electrically connected to the base region 41 of the one side region 30A inside the second emitter opening 272. The emitter terminal electrode 9 is electrically connected to the second contact electrode 273 on the interlayer insulating layer 61. The second contact electrode 273 may have a laminated structure which includes a barrier electrode layer and a main electrode layer, as with a first contact electrode 63. Otherwise, specific description of the second contact electrode 273 is omitted here.

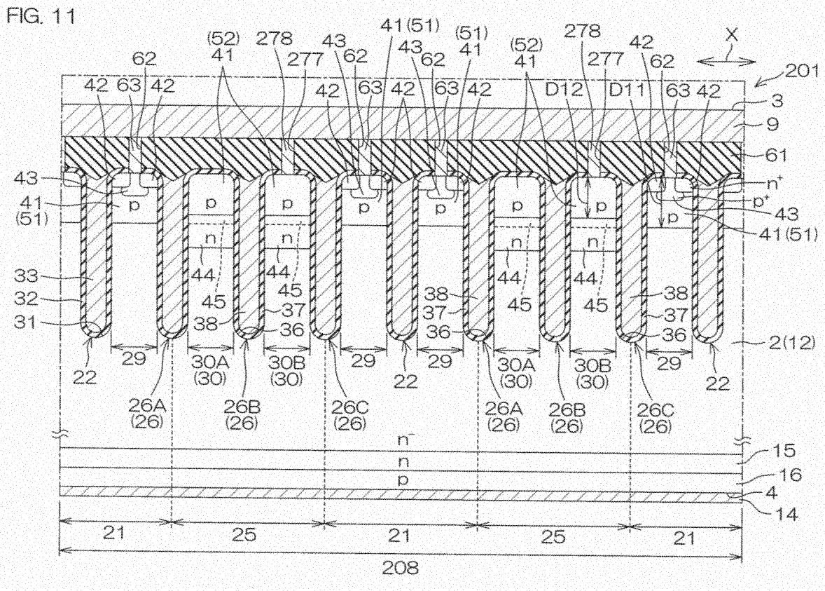

FIG. 11 is a cross-sectional view showing a third configuration example of the semiconductor device 201 according to the second embodiment of the present invention. FIG. 11 is a cross-sectional view corresponding to FIG. 5. In FIG. 11, the same reference signs as those of FIG. 9 are given to portions common to those of the first configuration example, and a specific description thereof is omitted. The third configuration example is different from the first configuration example in that an emitter terminal electrode 9 is electrically connected to a base region 41 of the other side region 30B in addition to a base region 41 of a first region 29 and is not connected to a base region 41 of the one side region 30A. That is, while the base region 41 of the other side region 30B is emitter-grounded, the base region 41 of the one side region 30A is formed in an electrically floating state.

Specifically, a third emitter opening 277 is formed at a position corresponding to the base region 41 of the other side region 30B in an interlayer insulating layer 61. The third emitter opening 277 vertically penetrates through the interlayer insulating layer 61 to expose the base region 41 of the other side region 30B. A third contact electrode 278 is embedded in the third emitter opening 277 of the interlayer insulating layer 61. The third contact electrode 278 is electrically connected to the base region 41 of the other side region 30B inside the third emitter opening 277. The emitter terminal electrode 9 is electrically connected to the third contact electrode 278 on the interlayer insulating layer 61. The third contact electrode 278 may have a laminated structure that includes a barrier electrode layer and a main electrode layer, as with a first contact electrode 63. Otherwise, specific description of the third contact electrode 278 is omitted here.

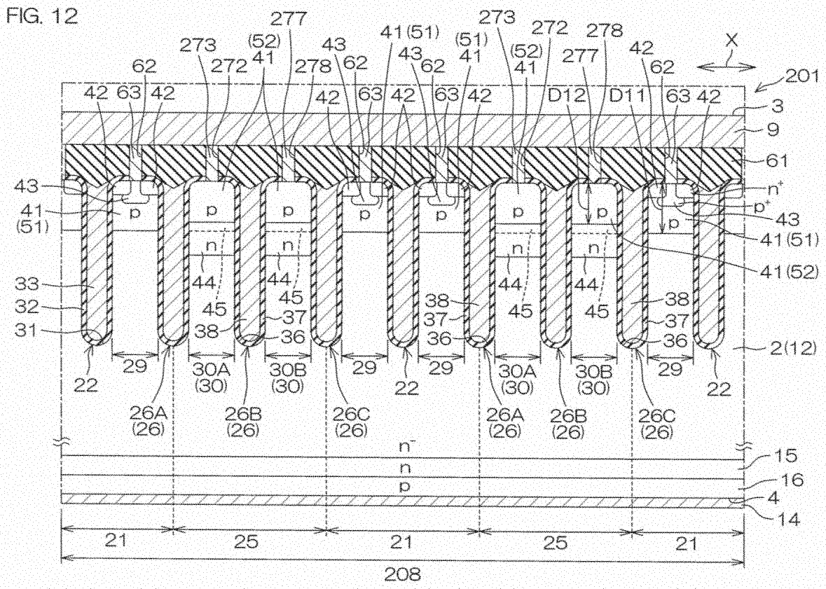

FIG. 12 is a cross-sectional view showing a fourth configuration example of the semiconductor device 201 according to the second embodiment of the present invention. FIG. 12 is a cross-sectional view which corresponds to FIG. 5. In FIG. 12, the same reference signs as those of FIG. 9 are given to portions common to those of the first configuration example, and a specific description thereof is omitted. The fourth configuration example is different from the first configuration example in that an emitter terminal electrode 9 is electrically connected to both of a base region 41 of the one side region 30A and a base region 41 of the other side region 30B in addition to a base region 41 of a first region 29. That is, the semiconductor device 201 according to the fourth configuration example includes a second emitter opening 272 and a second contact electrode 273 (refer to FIG. 10) as well as a third emitter opening 277 and a third contact electrode 278 (refer to FIG. 11).

The second contact electrode 273 is electrically connected to the base region 41 of the one side region 30A via the second emitter opening 272. The third contact electrode 278 is electrically connected to the base region 41 of the other side region 30B via the third emitter opening 277. The emitter terminal electrode 9 is electrically connected to the second contact electrode 273 and the third contact electrode 278 on an interlayer insulating layer 61.

Values of the saturation voltage VCE (sat) in the first to the fourth configuration example of the second embodiment are shown in Table 2 given below. Table 2 given below shows the values of the saturation voltage VCE (sat) when a rated collector current is 30 A.

TABLE 2

| | Vce (sat) (V) |
|---|---|
| First example | 1.50 |
| Second example | 1.58 |
| Third example | 1.56 |
| Fourth example | 1.60 |

Table 2 clearly shows that, in the second embodiment, in general, values of the saturation voltage VCE (sat) are larger than those of the reference examples. Therefore, a mode of the semiconductor device 201 is changed from the first reference example to the first to the fourth configuration example (that is, the high concentration region 44 is introduced), thus making it possible to adjust the values of the saturation voltage VCE (sat) without changing the basic layout. As described so far, according to this mode, it is possible to provide the semiconductor device 201 having a structure in which the saturation voltage VCE (sat) is adjusted by a novel structure.

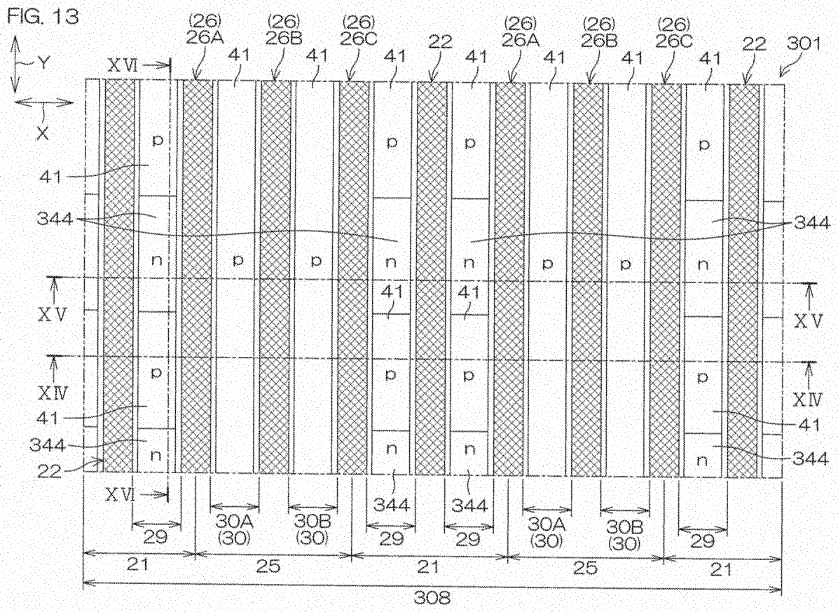

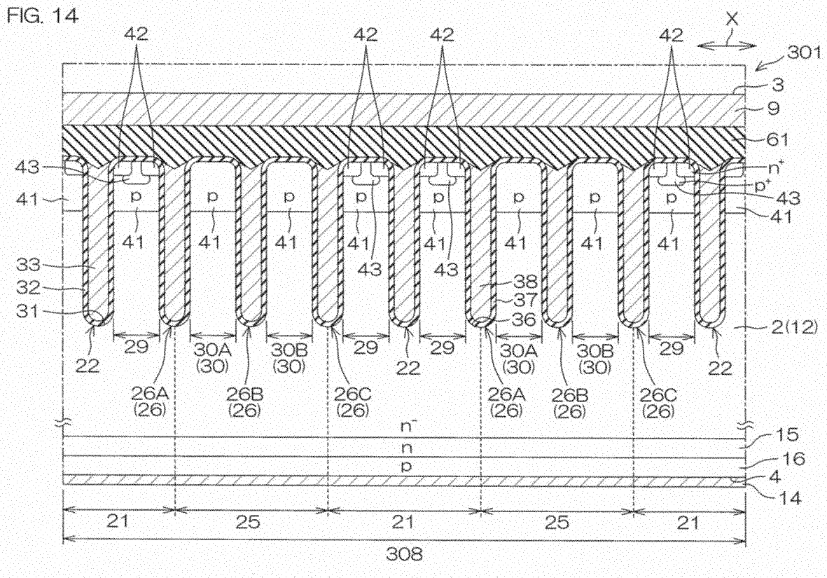

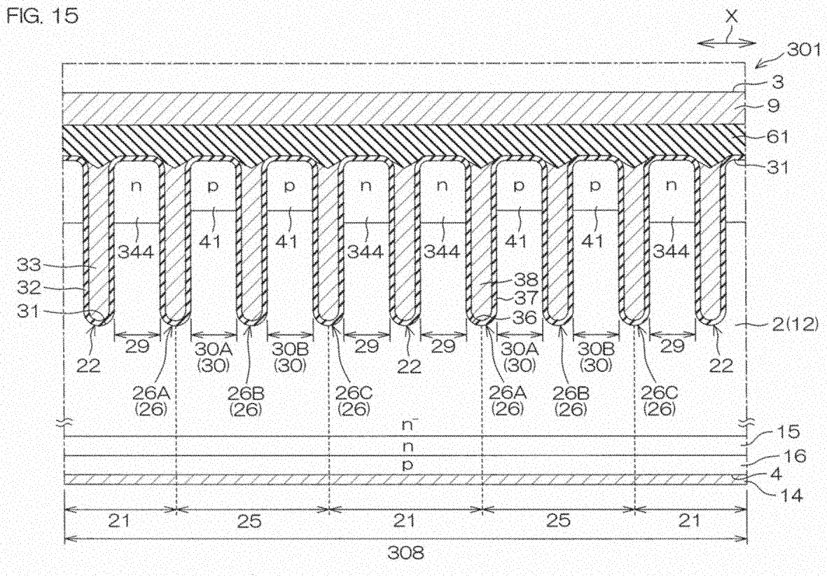

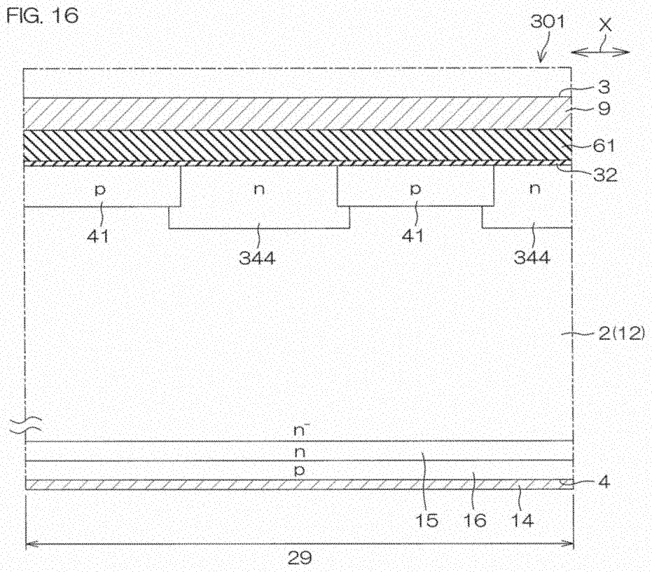

FIG. 13 is a plan view showing an internal structure of a semiconductor device 301 according to the third embodiment of the present invention. FIG. 14 is a cross-sectional view along line XIV-XIV shown in FIG. 13. FIG. 15 is a cross-sectional view along line XV-XV shown in FIG. 13. FIG. 16 is a cross-sectional view along line XVI-XVI shown in FIG. 15. In FIG. 13 to FIG. 16, the same reference signs as those of FIG. 1 to FIG. 5 are given to portions common to those of the first embodiment, and a specific description thereof is omitted.

With reference to FIG. 13 to FIG. 16, the semiconductor device 301 according to the third embodiment has an IGBT region 308 in place of the IGBT region 8. The IGBT region 308 is different from the IGBT region 8 according to the first embodiment in that a plurality of base regions 41 are formed at intervals in a first direction Y in a first region 29, and a high concentration region 344 is not connected to the base region 41 from a normal direction Z but is connected to the base region 41 from the first direction Y along a first principal surface 3. In this structure, an emitter region 42 and a contact region 43 are each formed in a surface layer portion of the base region 41 and is not formed in the surface layer portions of the plurality of high concentration regions 344. In other respects, the IGBT region 308 is common to the IGBT region 8 according to the first embodiment (the first configuration example thereof).

The high concentration region 344 corresponds to the aforementioned high concentration region 44. That is, the high concentration region 344 has an n type impurity concentration higher than a drift region 12. The high concentration region 344 is formed on one side of one of the first region 29 and a second region 30 and is not formed on the other side. In this mode, the high concentration region 344 is formed in the first region 29 and is not formed in the second region 30.

That is, in the IGBT region 308, the high concentration region 344 is formed only in a first region 29 of an FET structure 21 and the high concentration region 344 is not formed in the one side region 30A or the other side region 30B of a region separation structure 25. In this mode, the high concentration region 344 is formed in both of the two first regions 29. As a matter of course, there may be adopted such a mode that the high concentration region 344 is formed only in one of the two first regions 29 and the high concentration region 344 is not formed in the other of the two first regions 29.

The high concentration region 344 is formed alternately with the base region 41 in the first direction Y in the first region 29. In this mode, the plurality of high concentration regions 344 are alternately arranged with the plurality of base regions 41 in the first direction Y in a state that one base region 41 is held between the high concentration regions 344 from the first direction Y in the first region 29. The high concentration region 344 is connected to the base region 41 in the first region 29.

The high concentration region 344 is formed at a depth position between the first principal surface 3 and a bottom wall of a gate trench 31. The high concentration region 344 is formed at intervals from the bottom wall of the gate trench 31 on the first principal surface 3 side. The high concentration region 344 exposes a part of a side wall of the gate trench 31 and the bottom wall thereof. The high concentration region 344 faces a gate electrode 33 on the side wall of the gate trench 31, with a gate insulating film 32 held between the high concentration region 344 and the gate electrode 33.

The high concentration region 344 is formed at a depth position between the first principal surface 3 and a bottom wall of a separation trench 36. The high concentration region 344 is formed at intervals from the bottom wall of the separation trench 36 on the first principal surface 3 side. The high concentration region 344 exposes a part of a side wall of the separation trench 36 and the bottom wall thereof. The high concentration region 344 faces a separation electrode 38 on the side wall of the separation trench 36, with a separating/insulating film 37 held between the high concentration region 344 and the separation electrode 38.

The high concentration region 344 is formed so as to be deeper than the base region 41. A bottom portion of the high concentration region 344 may protrude to a bottom portion side of the base region 41 to cover the bottom portion of the base region 41. The high concentration region 344 may be approximately equal in depth to the base region 41 or may be shallower in depth than the base region 41. As described so far, according to this mode, it is possible to provide the semiconductor device 301 which has a structure having a saturation voltage VCE (sat) adjusted by a novel structure.

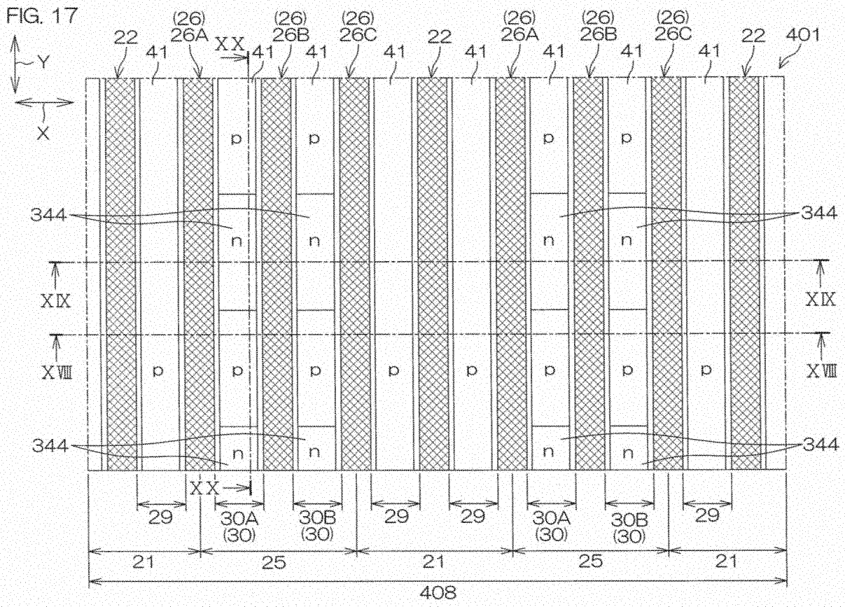

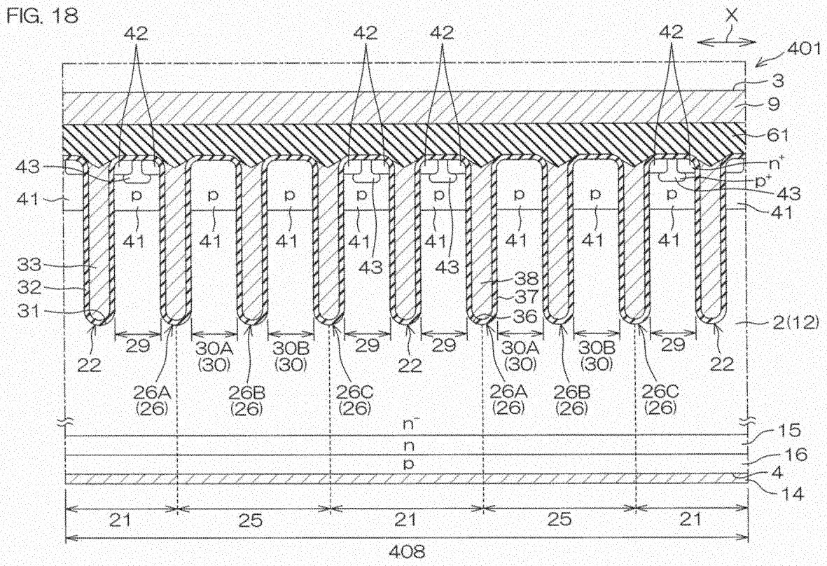

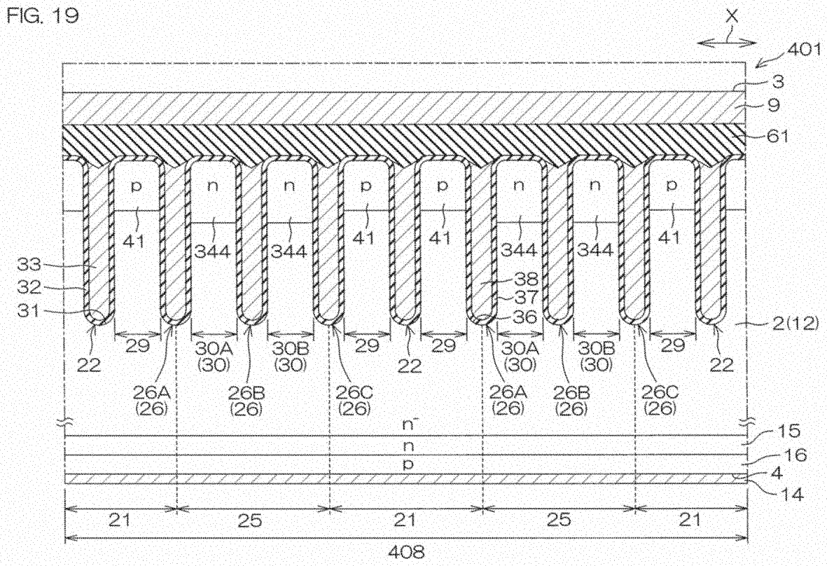

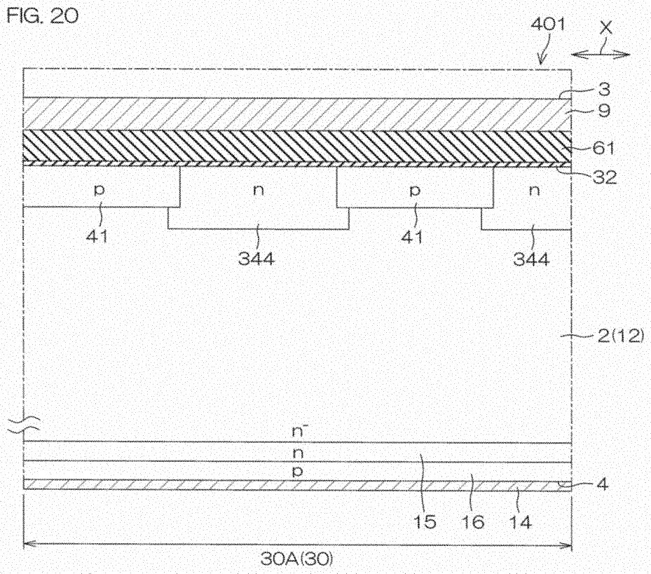

FIG. 17 is a plan view showing an internal structure of a semiconductor device 401 according to the fourth embodiment of the present invention. FIG. 18 is a cross-sectional view along line XVIII-XVIII shown in FIG. 17. FIG. 19 is a cross-sectional view along line XIX-XIX shown in FIG. 17. FIG. 20 is a cross-sectional view along line XX-XX in FIG. 17. In FIG. 17 to FIG. 20, the same reference signs as those of FIG. 17 to FIG. 20 are given to portions common to those of the third embodiment, and a specific description thereof is omitted.

The semiconductor device 401 according to the fourth embodiment has an IGBT region 408 in place of the IGBT region 308. The IGBT region 408 is different from the IGBT region 8 according to the first embodiment in that a high concentration region 344 is formed in a second region 30 (one side region 30A and the other side region 30B) of a region separation structure 25. Then, a high concentration region is not formed in a first region 29 of an FET structure 21.

The high concentration region 344 is connected to a base region 41 in the second region 30. The high concentration region 344 is formed at a depth position between a first principal surface 3 and a bottom wall of a gate trench 31. The high concentration region 344 is formed at intervals from a bottom wall of a separation trench 36 on the first principal surface 3 side. The high concentration region 344 exposes a part of a side wall of the separation trench 36 and the bottom wall thereof. The high concentration region 344 faces a separation electrode 38 in a side wall of the separation trench 36, with a separating/insulating film 37 held between the high concentration region 344 and the separation electrode 38.

A bottom portion of the high concentration region 344 is formed in a region between the first principal surface 3 and the bottom wall of the separation trench 36 with respect to a normal direction Z. As shown in FIG. 20, the bottom portion of the high concentration region 344 is formed in a region between a bottom portion of the base region 41 and a second principal surface 4 with respect to the normal direction Z. That is, the high concentration region 344 is formed so as to be deeper than the base region 41. As shown in FIG. 20, the bottom portion of the high concentration region 344 is positioned further above than a central position of a separation trench structure 26 in a depth direction with respect to the normal direction Z. That is, the high concentration region 344 is formed so as to be shallower than the central position of the separation trench structure 26 in the depth direction.

Further, as shown in FIG. 20, at the bottom portion of the high concentration region 344, a part of the high concentration region 344 may protrude in a second direction X and reach a region below the base region 41. Still further, the high concentration region 344 may be approximately equal in depth to the base region 41 or the high concentration region 344 may be formed so as to be shallower than the base region 41. As described so far, according to this mode, it is possible to provide the semiconductor device 401 having a structure in which a saturation voltage VCE (sat) is adjusted by a novel structure.

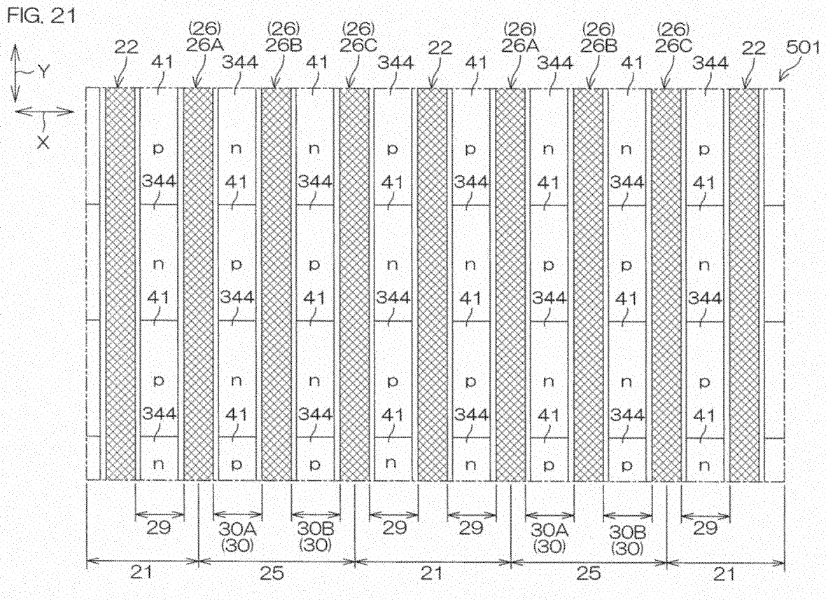

FIG. 21 is a plan view showing an internal structure of a semiconductor device 501 according to the fifth embodiment of the present invention. In FIG. 21, the same reference signs as those of FIG. 13 to FIG. 20 are given to portions common to those of the third embodiment and the fourth embodiment, and a specific description thereof is omitted. The semiconductor device 501 according to the fifth embodiment has a structure in which the structure according to the third embodiment is combined with the structure according to the fourth embodiment. That is, in the semiconductor device 501, a high concentration region 344 is formed in both of a first region 29 and a second region 30.

A plurality of base regions 41 are formed at intervals in a first direction Y on the first region 29 side. On the first region 29 side, the plurality of high concentration regions 344 are formed at intervals in the first direction Y. On the first region 29 side, the plurality of high concentration regions 344 are alternately arranged with a plurality of base regions 41. On the second region 30 side, the plurality of base regions 41 are formed at intervals in the first direction Y. On the second region 30 side, the plurality of high concentration regions 344 are formed at intervals in the first direction Y. On the second region 30 side, the plurality of high concentration regions 344 are alternately arranged with the plurality of base regions 41.

The plurality of base regions 41 on the second region 30 side are formed so as to deviate in the first direction Y with respect to the plurality of base regions 41 on the first region 29 side. The plurality of base regions 41 on the second region 30 side may deviate in the first direction Y so as not to face the plurality of base regions 41 on the first region 29 side in a second direction X. The plurality of base regions 41 on the second region 30 side face the plurality of high concentration regions 344 on the first region 29 side in the second direction X. The plurality of high concentration regions 344 on the second region 30 side face the plurality of base regions 41 on the first region 29 side in the second direction X.

From a different point of view, the plurality of high concentration regions 344 of the first region 29 face the plurality of base regions 41 of the second region 30 in the second direction X. Further, the plurality of base regions 41 of the first region 29 face the plurality of high concentration regions 344 of the second region 30 in the second direction X. As shown in FIG. 21, the high concentration region 344 may be formed in both of the two first regions 29 which are adjacent to each other. The high concentration region 344 may be formed only in one of the two first regions 29.

Further, in this mode, the high concentration region 344 of the first region 29 may face the base region 41 of the first region 29 in the second direction X. Then, the high concentration region 344 of the second region 30 may face the base region 41 of the second region 30 in the second direction X. As described so far, according to this mode, it is possible to provide the semiconductor device 501 having a structure in which a saturation voltage VCE (sat) is adjusted by a novel structure.

The present invention can be carried out in still another mode. In each of the aforementioned embodiments, the semiconductor layer 2 may have a laminated structure which includes a p type semiconductor substrate in place of an n type semiconductor substrate 13 and an n type epitaxial layer formed on the semiconductor substrate. In this case, the p type semiconductor substrate corresponds to the collector region 16. Further, the n⁻ type epitaxial layer corresponds to the drift region 12. In this case, the p type semiconductor substrate may be made of silicon. The n⁻ type epitaxial layer may be made of silicon. The n⁻ type epitaxial layer is formed by epitaxially-growing silicon from a principal surface of the p type semiconductor substrate.

In the aforementioned embodiments, a description has been given of an example in which the first conductive type is an n type and the second conductive type is a p type. However, the first conductive type may be a p type and the second conductive type may be an n type. A specific constitution of this case is obtained by replacing the n type region with the p type region and replacing the p type region with the n type region in the aforementioned description and attached drawings.

Examples of features extracted from this description and from the drawings will be hereinafter shown. Hereinafter, there is provided a semiconductor device which has a novel structure.

[A1] A semiconductor device including a semiconductor layer which has a first principal surface on one side and a second principal surface on the other side, a first conductive type drift region which is formed inside the semiconductor layer, a second conductive type base region which is formed on a surface layer portion of the drift region, a plurality of trench structures which includes a first trench structure, a second trench structure and a third trench structure that are formed at intervals on the first principal surface so as to penetrate through the base region, a first region which is partitioned between the first trench structure and the second trench structure in the semiconductor layer, a second region which is partitioned between the second trench structure and the third trench structure in the semiconductor layer, a channel region which is controlled by the first trench structure, and a first conductive type high concentration region which has a first conductive type impurity concentration higher than the drift region and is formed in a region on the second principal surface side with respect to the base region on one side of one of the first region and the second region and is not formed on the other side of the first region or the second region.

[A2] The semiconductor device described in A1 in which the base region on one side of the first region and the second region is formed so as to be shallower than the base region on the other side of the first region and the second region.

[A3] The semiconductor device described in A1 or A2 further including a first conductive type emitter region which is formed in a region along the first trench structure on a surface layer portion of the base region of the first region to demarcate the channel region with the drift region.

[A4] The semiconductor device described in any one of A1 to A3 in which a gate potential is applied to the first trench structure, an emitter potential is applied to the second trench structure, and the emitter potential is applied to the third trench structure.

[A5] The semiconductor device described in any one of A1 to A4 further including an electrode which is electrically connected to the first region on the first principal surface.

[A6] The semiconductor device described in any one of A1 to A5 in which the high concentration region is formed so as to be shallower than a central position of the plurality of trench structures in a depth direction.

[A7] The semiconductor device described in any one of A1 to A5 in which the high concentration region is formed so as to be deeper than the central position of the plurality of trench structures in the depth direction.

[A8] The semiconductor device described in any one of A1 to A7 in which the plurality of trench structures extend in a band shape in one direction in a plan view and the high concentration region extends in one direction in a plan view.

[A9] The semiconductor device described in any one of A1 to A8 in which the high concentration region is formed in the first region and is not formed in the second region.

[A10] The semiconductor device described in any one of A1 to A8 in which the high concentration region is formed in the second region and is not formed in the first region.

[A11] A semiconductor device including a semiconductor layer which has a first principal surface on one side and a second principal surface on the other side, a first conductive type drift region which is formed inside the semiconductor layer, a second conductive type base region which is formed on a surface layer portion of the drift region, a plurality of trench structures which include a first trench structure, a second trench structure and a third trench structure that are formed at intervals on the first principal surface so as to penetrate through the base region, a first region which is partitioned between the first trench structure and the second trench structure in the semiconductor layer, a second region which is partitioned between the second trench structure and the third trench structure in the semiconductor layer, a channel region which is controlled by the first trench structure, and a first conductive type high concentration region which has a first conductive type impurity concentration higher than the drift region and is formed on a surface layer portion of the drift region so as to be connected to the base region from one direction along the first principal surface at least on one side of the first region and the second region.

[A12] The semiconductor device described in A11 in which the base region is formed at a first depth in a thickness direction of the semiconductor layer from the first principal surface, and the high concentration region is formed at a second depth exceeding the first depth in the thickness direction of the semiconductor layer from the first principal surface.

[A13] The semiconductor device described in A11 or A12 further including a first conductive type emitter region which is formed on a surface layer portion of the base region of the first region to demarcate the channel region with the drift region.

[A14] The semiconductor device described in any one of A11 to A13 in which a gate potential is applied to the first trench structure, an emitter potential is applied to the second trench structure and the emitter potential is applied to the third trench structure.

[A15] The semiconductor device described in any one of A11 to A14 further including an electrode which is electrically connected to the first region on the first principal surface.

[A16] The semiconductor device described in any one of A11 to A15 in which the high concentration region is alternately arranged with the base region in one direction.

[A17] The semiconductor device described in any one of A11 to A16 in which the high concentration region is formed in the first region and is not formed in the second region.

[A18] The semiconductor device described in A17 in which the plurality of trench structures are formed in a band shape extending in one direction, the plurality of first regions are partitioned at intervals in an intersecting direction which intersects in one direction, the plurality of second regions are partitioned at intervals in the intersecting direction, and the high concentration region is formed at least in one of the plurality of first regions.

[A19] The semiconductor device described in any one of A11 to A16 in which the high concentration region is formed in the second region and is not formed in the first region.

[A20] The semiconductor device described in A19 in which the plurality of trench structures are formed in a band shape extending in one direction, the plurality of first regions are partitioned at intervals in an intersecting direction which intersects in one direction, the plurality of second regions are partitioned at intervals in the intersecting direction, and the high concentration region is formed at least in one of the plurality of second regions.

[A21] The semiconductor device described in any one of A11 to A16 in which the high concentration region is formed in both of the first region and the second region.

[A22] The semiconductor device described in A21 in which the plurality of trench structures are formed in a band shape extending in one direction, the plurality of first regions are partitioned at intervals in an intersecting direction which intersects in one direction, the plurality of second regions are partitioned at intervals in the intersecting direction, and the high concentration region is formed at least in one of the plurality of first regions and at least in one of the plurality of second regions.

[A23] The semiconductor device described in A22 in which the high concentration region of the first region faces the base region of the second region in the intersecting direction, and the high concentration region of the second region faces the base region of the first region in the intersecting direction.

While the embodiments have been described in detail, these are merely specific examples used to clarify the technical contents of the present invention and the present invention should not be interpreted as being limited to these specific examples and the scope of the present invention is to be limited by the appended claims.

### REFERENCE SIGNS LIST

1 semiconductor device
2 semiconductor layer
3 first principal surface
4 second principal surface
12 drift region
22 trench gate structure (first trench structure)
26 separation trench structure (second trench structure, third trench structure)
26A first separation trench structure (second trench structure)
26B second separation trench structure (third trench structure)
29 first region
30 second region
41 base region
44 high concentration region
201 semiconductor device
301 semiconductor device
344 high concentration region
401 semiconductor device
501 semiconductor device

1. A semiconductor device comprising:
a semiconductor layer which has a first principal surface on one side and a second principal surface on the other side;
a first conductive type drift region which is formed inside the semiconductor layer;
a second conductive type base region which is formed on a surface layer portion of the drift region;
a plurality of trench structures which include a first trench structure, a second trench structure and a third trench structure that are formed at intervals on the first principal surface so as to penetrate through the base region;
a first region which is partitioned between the first trench structure and the second trench structure in the semiconductor layer;
a second region which is partitioned between the second trench structure and the third trench structure in the semiconductor layer;
a channel region which is controlled by the first trench structure; and
a first conductive type high concentration region which has a first conductive type impurity concentration higher than the drift region and is formed in a region on the second principal surface side with respect to the base region on one side of one of the first region and the second region and is not formed on the other side of the first region or the second region.

2. The semiconductor device according to claim 1, wherein the base region on one side of the first region and the second region is formed so as to be shallower than the base region on the other side of the first region and the second region.

3. The semiconductor device according to claim 1 further comprising: a first conductive type emitter region which is formed in a region along the first trench structure in a surface layer portion of the base region of the first region to demarcate the channel region with the drift region.

4. The semiconductor device according to claim 1, wherein a gate potential is applied to the first trench structure,
an emitter potential is applied to the second trench structure, and
the emitter potential is applied to the third trench structure.

5. The semiconductor device according to claim 1, wherein the high concentration region is formed so as to be shallower than a central position of the plurality of trench structures in a depth direction.

6. The semiconductor device according to claim 1, wherein the high concentration region is formed so as to be deeper than the central position of the plurality of trench structures in the depth direction.

7. The semiconductor device according to claim 1, wherein the high concentration region is formed in the first region and is not formed in the second region.

8. The semiconductor device according to claim 1, wherein the high concentration region is formed in the second region and is not formed in the first region.

9. The semiconductor device according to claim 1, further comprising: an electrode which is electrically connected to the first region on the first principal surface.

10. A semiconductor device comprising:
a semiconductor layer which has a first principal surface on one side and a second principal surface on the other side;
a first conductive type drift region which is formed inside the semiconductor layer;
a second conductive type base region which is formed on a surface layer portion of the drift region;
a plurality of trench structures which include a first trench structure, a second trench structure and a third trench structure that are formed at intervals on the first principal surface so as to penetrate through the base region;
a first region which is partitioned between the first trench structure and the second trench structure in the semiconductor layer;
a second region which is partitioned between the second trench structure and the third trench structure in the semiconductor layer;
a channel region which is controlled by the first trench structure; and
a first conductive type high concentration region which has a first conductive type impurity concentration higher than the drift region and is formed on a surface layer portion of the drift region so as to be connected to the base region in one direction along the first principal surface at least on one side of the first region and the second region.

11. The semiconductor device according to claim 10, wherein the base region is formed at a first depth in a thickness direction of the semiconductor layer from the first principal surface, and
the high concentration region is formed at a second depth which exceeds the first depth in the thickness direction of the semiconductor layer from the first principal surface.

12. The semiconductor device according to claim 10 further comprising a first conductive type emitter region which is formed on a surface layer portion of the base region of the first region to demarcate the channel region with the drift region.

13. The semiconductor device according to claim 10, wherein a gate potential is applied to the first trench structure,
an emitter potential is applied to the second trench structure, and
the emitter potential is applied to the third trench structure.

14. The semiconductor device according to claim 10, wherein the high concentration region is alternately arranged with the base region in one direction.

15. The semiconductor device according to claim 10, wherein the high concentration region is formed in the first region and is not formed in the second region.

16. The semiconductor device according to claim 15, wherein the plurality of trench structures are formed in a band shape extending in one direction,
the plurality of first regions are partitioned at intervals in an intersecting direction which intersects in one direction,
the plurality of second regions are partitioned at intervals in the intersecting direction, and
the high concentration region is formed at least in one of the plurality of first regions.

17. The semiconductor device according to claim 10, wherein the high concentration region is formed in the second region and is not formed in the first region.

18. The semiconductor device according to claim 17, wherein the plurality of trench structures are formed in a band shape along the one direction,
the plurality of first regions are partitioned at intervals in an intersecting direction which intersects in one direction,
the plurality of second regions are partitioned at intervals in the intersecting direction, and
the high concentration region is formed at least in one of the plurality of second regions.

19. The semiconductor device according to claim 10, wherein the high concentration region is formed in both of the first region and the second region.

20. The semiconductor device according to claim 19, wherein the plurality of trench structures are formed in a band shape extending in one direction,
the plurality of first regions are partitioned at intervals in an intersecting direction which intersects in one direction,
the plurality of second regions are partitioned at intervals in the intersecting direction, and
the high concentration region is formed at least in one of the plurality of first regions and at least in one of the plurality of second regions.
